(19) United States
(12) Patent Application Publication
(10) Pub. No.: US 2025/0192074 A1
(43) Pub. Date: Jun. 12, 2025

(54) ELECTRONIC PACKAGE AND METHOD FOR FABRICATING THE SAME

(71) Applicant: SILICONWARE PRECISION INDUSTRIES CO., LTD., Taichung City (TW)

(72) Inventors: Chung-Chih YEN, Taichung City (TW); Chun-Chu LAI, Taichung City (TW)

(21) Appl. No.: 18/819,585

(22) Filed: Aug. 29, 2024

(30) Foreign Application Priority Data
Dec. 12, 2023 (TW) 112148324

(51) Int. Cl. H01L 23/58; H01L 21/48; H01L 21/56; H01L 23/00; H01L 23/31; H01L 23/498; H01L 25/065

(52) U.S. Cl. CPC H01L 23/585; H01L 21/4857; H01L 21/565; H01L 21/568; H01L 23/3135; H01L 23/49822; H01L 24/16; H01L 24/32; H01L 24/73; H01L 25/0652; H01L 2224/16227; H01L 2224/32225; H01L 2224/73204; H01L 2924/3511

(57) ABSTRACT

An electronic package and a method for fabricating the same are provided. The electronic package includes a cladding layer embedded with a first electronic component and a plurality of conductive pillars; a circuit structure provided on one surface of the cladding layer; a second electronic component disposed on the circuit structure; an insulating layer disposed on another surface of the cladding layer; and a circuit portion disposed on the insulating layer. It can adjust the deformation of the electronic package by changing the diametric sizes of the plurality of conductive pillars.

### CROSS-REFERENCE TO RELATED APPLICATIONS

The present application is based upon and claims the right of priority to TW Patent Application No. 112148324, filed Dec. 12, 2023, the disclosure of which is hereby incorporated by reference herein in its entirety for all purposes.

### BACKGROUND

### 1. Technical Field

The present disclosure relates to a semiconductor packaging technology, and more particularly, to an electronic package and a method for fabricating the same.

### 2. Description of Related Art

As high-performance computing (HPC) technology becomes increasingly important and widespread in today's life, such as the development of medical technology, the development of cancer drugs, or the automatic sensing and detection calculation of self-driving vehicles, etc., the packaging structure used by equipment applied in these fields is mostly a fan-out package (FOPKG) structure. For example, structures such as Fan-Out Multi-Chip Module (FOMCM) and Fan-out embedded bridge die (FOEB) meet the requirements of multi-chip/high number of circuit layers/large fan-out size/high heat dissipation design.

Please refer to FIG. 1, which depicts a conventional fan-out package (FOPKG) structure in which a chip 11 is mainly embedded in a cladding layer 15, and a redistribution layer (RDL) 10 is formed above, and then function chips 16 are placed on the redistribution layer 10. This configuration enables the function chips 16 and the chip 11 embedded in the cladding layer 15 to communicate vertically, thereby meeting the requirements of high-speed transmission.

However, the FOPKG process is performed in a monolithic structure such as wafer form. At each station of a step of the process, due to the mismatch in the coefficient of thermal expansion between a carrier and the upper dielectric layer and the metal layer, warpage problems may occur, such that some areas of the wafer form present a smiling face (concave center), while some areas present a crying face (convex center). If the warpage level of a crying face or a smiling face is too high, the wafer form may not be loaded into the machine, and the manufacturing process may not be able to proceed. In addition, when the product is manufactured and removed from the carrier to be singulated into individual package forms, the warpage problems may occur in the FOPKG, causing reliability issues as the FOPKG is disposed on and connected to the circuit board of the final product.

Therefore, how to overcome the above-mentioned problems of conventional techniques has become an urgent issue to be solved.

### SUMMARY

In view of the various shortcomings of the prior art, the present disclosure provides a method for fabricating an electronic package, comprising: providing a carrier; forming a plurality of conductive pillars on the carrier, and disposing a first electronic component on the carrier, wherein the plurality of conductive pillars surround the first electronic component, and diametric sizes of the plurality of conductive pillars gradually increase or decrease from an outside to a center of the carrier; forming a cladding layer on the carrier to encapsulate the first electronic component and the conductive pillars, wherein the cladding layer has a first surface and a second surface opposing the first surface, end surfaces of the plurality of conductive pillars are exposed from the first surface of the cladding layer, and the cladding layer is bonded to the carrier with the second surface thereof, and removing the carrier.

The present disclosure further provides an electronic package, comprising: a cladding layer having a first surface and second surface opposing the first surface; a first electronic component embedded in the cladding layer; and a plurality of conductive pillars embedded in the cladding layer and surrounding the first electronic component, wherein the diametric sizes of the plurality of conductive pillars gradually increase or decrease from an outside to a center with respect to the cladding layer, and end surfaces of the plurality of conductive pillars are exposed from the first surface of the cladding layer.

In the aforementioned electronic package and the method for fabricating the same, further comprising forming a circuit structure on the first surface of the cladding layer to electrically connect the plurality of conductive pillars and the first electronic component.

In the aforementioned electronic package and the method for fabricating the same, further comprising disposing a second electronic component on the circuit structure which is not in contact with the cladding layer, and electrically connecting the second electronic component to the circuit structure.

In the aforementioned electronic package and the method for fabricating the same, wherein the first electronic component is bonded with and electrically connected to a plurality of conductors.

In the aforementioned electronic package and the method for fabricating the same, wherein the second electronic component is disposed on the circuit structure through a plurality of conductive bumps and electrically connected to the circuit structure.

In the aforementioned electronic package and the method for fabricating the same, further comprising forming a circuit portion on the second surface of the cladding layer to electrically connect the plurality of conductive pillars.

In the aforementioned electronic package and the method for fabricating the same, further comprising forming a plurality of conductive components on the circuit portion.

In the aforementioned electronic package and the method for fabricating the same, which is performed on a wafer comprising a plurality of packaging units, and an entire semi-finished product of the wafer is produced station by station in advance, wherein diametric sizes of a plurality of conductive pillars are kept uniform, then warping contours of each of the packaging units presented in process are recorded, and warping contours of each of the packaging units after singulation are recorded, so as to design a distribution of the diametric sizes of the plurality of conductive pillars in accordance with recorded of the warping contours, such that the diametric sizes of the plurality of conductive pillars are designed to decrease from the outside to the center of the carrier when a deformation direction of the packaging units is a crying face, and the diametric sizes of the plurality of conductive pillars are designed to increase from the outside to the center of the carrier when the deformation direction of the packaging units is a smiling face.

It can be seen from the above, the electronic package and the method for fabricating the same of the present disclosure reduce the deformation problem through adjusting the ratio of diametric sizes of the conductive pillars then improve yield, mainly by recording in advance that when the deformation direction of the packaging structure is a crying face, the diametric sizes of the conductive pillars are reduced from the outside to the center, and when the deformation direction of the packaging structure is a smiling face, the diametric sizes of the conductive pillars are increased from the outside to the center. In addition, the aforementioned structure does not require the addition of new development for processes and materials or the purchase of machines, existing materials and original processes and machines can be used to solve the industry's existing technical problems, so there will be no large additional costs.

### BRIEF DESCRIPTION OF THE DRAWINGS

FIG. 1 is a schematic cross-sectional view of a conventional fan-out packaging structure.

FIG. 2A-1 to FIG. 2F-1 are schematic cross-sectional views illustrating a method for fabricating an electronic package according to the present disclosure.

FIG. 2A-2 is a schematic cross-sectional view illustrating another embodiment of the electronic package shown in FIG. 2A-1.

FIG. 2F-2 is a schematic cross-sectional view illustrating another embodiment of the electronic package shown in FIG. 2F-1.

### DETAILED DESCRIPTION

Implementations of the present disclosure are illustrated using the following embodiments. One of ordinary skill in the art can readily appreciate other advantages and technical effects of the present disclosure upon reading the contents of this specification.

It should be noted that the structures, ratios, sizes, etc. shown in the drawings appended to this specification are to be construed in conjunction with the disclosure of this specification in order to facilitate understanding of those skilled in the art. They are not intended to limit the implementations of the present disclosure, and therefore have no substantial technical meaning. Any modifications of the structures, changes in the ratio relationships or adjustments of the sizes, are to be construed as falling within the scope of the technical content disclosed herein to the extent of not causing changes in the technical effects created and the objectives achieved by the present disclosure. Meanwhile, terms such as “on,” “first,” “second,” “a,” and the like recited herein are for illustrative purposes, and are not intended to limit the scope in which the present disclosure can be implemented. Any variations or modifications of their relative relationships, without changing the substantial technical content, should also to be considered within the scope in which the present disclosure can be implemented.

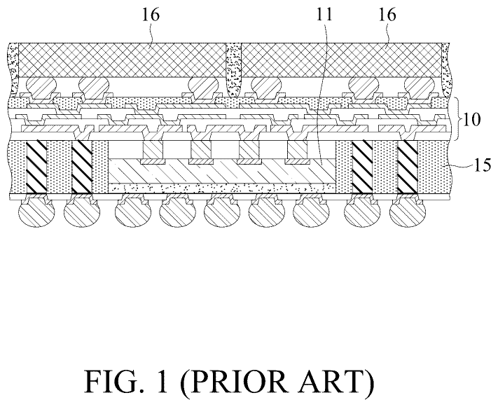

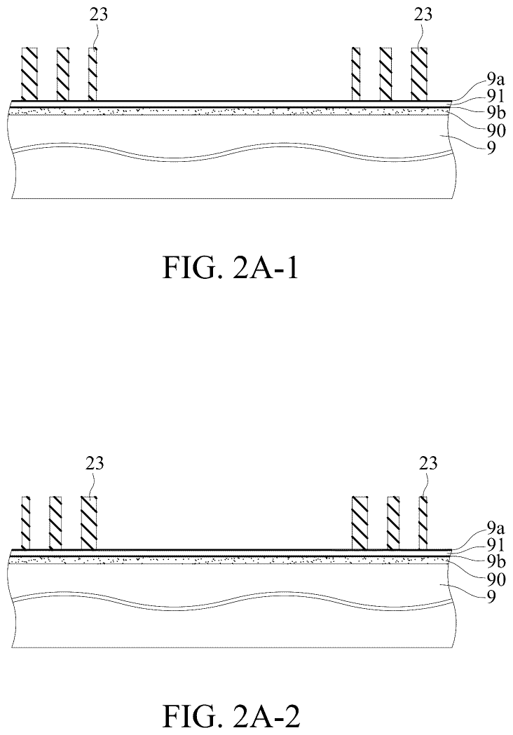

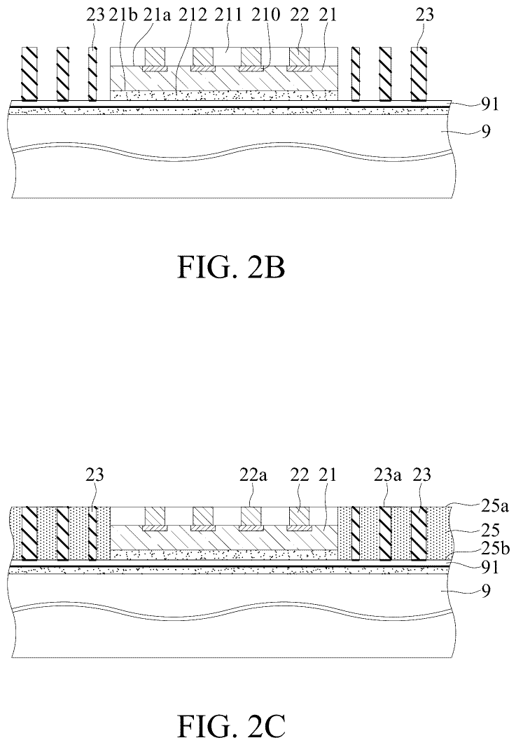

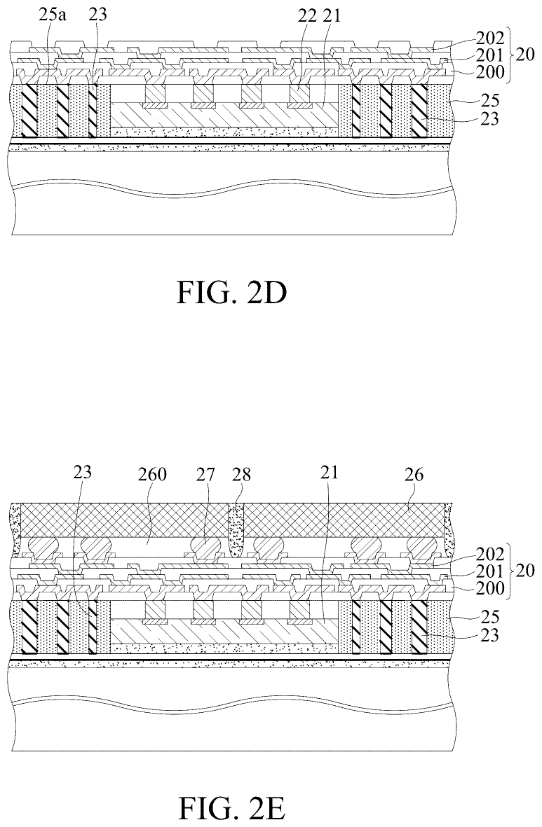

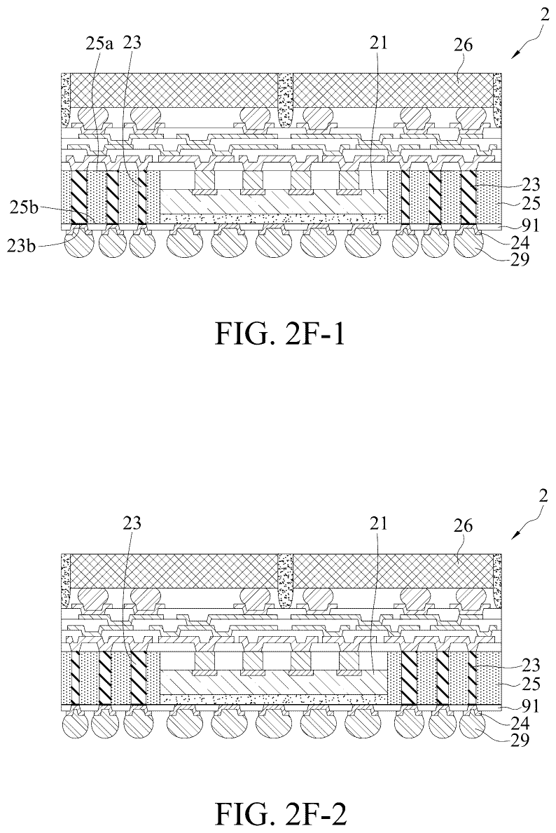

FIG. 2A-1 to FIG. 2F-1 are schematic cross-sectional views illustrating a method for fabricating an electronic package 2 according to the present disclosure.

As shown in FIG. 2A-1, a carrier 9 is provided, and a plurality of conductive pillars 23 are formed on the carrier 9. In an embodiment, the carrier 9 is, for example, a board made of semiconducting material (such as silicon or glass), on which a release layer 90, a metal layer 9b (such as titanium/copper), and an insulating layer 91 (such as a dielectric material or a solder-proof material) are sequentially formed, for instance, by coating, for a seed layer 9a to be disposed on the insulating layer 91. Further, a patterned resist layer (not shown) may be formed on the seed layer 9a to expose part of a surface of the seed layer 9a for forming the plurality of conductive pillars 23. In addition, the conductive pillars 23 are made of a metal material such as copper or a solder material, and the seed layer 9a is made of, for example, titanium/copper.

In an embodiment, the widths of the plurality of conductive pillars 23 gradually decrease from an outside to a center (as shown in FIG. 2A-1). In another embodiment, the widths of the plurality of conductive pillars 23 gradually increase from the outside to the center (as shown in FIG. 2A-2).

It should be noted that the electronic package of the present disclosure is performed based on a monolithic structure such as wafer form, which comprises a plurality of packaging units, only a single one packaging unit being shown in the drawings in this embodiment. In practice, a semi-finished product in an entire wafer form is made station by station first (the diametric sizes of the plurality of conductive pillars in the semi-finished product are kept uniform), then warping contours of each of the packaging units presented in process are recorded, and warping contours of each of the packaging units after singulation are recorded again, then a distribution of diametric sizes of the plurality of conductive pillars is designed in accordance with the recorded warping contours. For example, as the deformation direction of the packaging units is a crying face (i.e., using a horizontal plane as the reference, and the central area is higher than the peripheral area), the (transverse) sizes of the plurality of conductive pillars of the packaging unit decrease from the outside to the center (as shown in FIG. 2A-1), as the deformation direction of the packaging units is a smiling face (i.e., using a horizontal plane as the reference, and the central area is higher than the peripheral area), the (transverse) sizes of the plurality of conductive pillars of the packaging unit increase from the outside to the center (as shown in FIG. 2A-2). That is, the present disclosure records the fabricating process of each packaging unit in advance or when the deformation direction presented at the end is a crying face, the plurality of conductive pillars are designed to be gradually thinner from the outside to the inside; in contrast, when the deformation direction presented is a smiling face, the plurality of conductive pillars are designed to be gradually thicker from the outside to the inside.

As shown in FIG. 2B, after the conductive pillars 23 are formed, the patterned resist layer and the seed layer 9a beneath the patterned resist layer are removed, and at least one first electronic component 21 is disposed on the carrier 9 and surrounded by the plurality of conductive pillars 23, wherein the first electronic component 21 is bonded with and electrically connected to a plurality of conductors 22. The plurality of conductors 22 are, but not limited to, spherical conductive parts such as solder balls, or columnar conductive parts such as copper pillars or solder bumps or other metallic material, or stud-shaped conductive parts made by wire bonding machines.

In addition, the first electronic component 21 is an active component, a passive component, or a combination thereof, and the active component is, for example, a semiconductor chip, the passive component is such as a resistor, a capacitor or an inductor. In an embodiment, the first electronic component 21 is a semiconductor chip having an active surface 21a and an inactive surface 21b opposing the active surface 21a, the electronic component 21 is adhered onto the insulating layer 91 with its inactive surface 21b through a bonding layer 212, while the active surface 21a has a plurality of electrode pads 210 and a protective film 211 such as a passivation material formed thereon, and the conductors 22 are disposed on the electrode pads 210 and embedded in the protective film 211.

As shown in FIG. 2C, a cladding layer 25 is formed on the insulating layer 91 of the carrier 9 to encapsulate the first electronic component 21, the conductors 22 and the plurality of conductive pillars 23, wherein the cladding layer 25 has a first surface 25a and a second surface 25b opposing the first surface 25a. The protective film 211, the end surfaces 22a of the plurality of conductors 22 and the end surfaces 23a of the plurality of conductive pillars 23 are exposed from the first surface 25a of the cladding layer 25, such that the cladding layer 25 is bonded to the insulating layer 91 of the carrier 9 with its second surface 25b.

In an embodiment, the cladding layer 25 is insulation material, such as polyimide (PI), dry film, or a molding compound such as epoxy. For example, the process for making the cladding layer 25 may be formed on the insulating layer 91 by lamination, or compression molding, etc.

Furthermore, the first surface 25a of the cladding layer 25 can be flushed with the protective film 211, the end surfaces 23a of the plurality of conductive pillars 23 and the end surfaces 22a of the plurality of conductors 22 via a leveling process, so that the end surfaces 23a of the plurality of conductive pillars 23 and the end surfaces 22a of the plurality of conductors 22 are exposed from the first surface 25a of the cladding layer 25. For example, the leveling process removes part of the material of the protective film 211, part of the material of the plurality of conductive pillars 23, part of the material of the plurality of conductors 22 and part of the material of the cladding layer 25 through grinding.

In addition, the other end surfaces 23b (the seed layer 9a is ignored) of the plurality of conductive pillars 23 may also be roughly flushed with the second surface 2b of the cladding layer 25.

As shown in FIG. 2D, a circuit structure 20 is formed on the first surface 25a of the cladding layer 25 and electrically connected to the plurality of conductive pillars 23 and the plurality of conductors 22.

In an embodiment, the circuit structure 20 comprises a plurality of insulating layers 200 and a plurality of redistribution layers (RDLs) 201 disposed on the insulating layers 200, wherein an outermost insulating layer 200 may be a solder mask layer. The outermost redistribution layer 201 is exposed from the solder mask layer to serve as electrical contact pads 202, such as a micro pad (known as μ-pad). Alternatively, the circuit structure 20 may only comprise a single insulating layer 200 and a single redistribution layer 201.

Furthermore, the redistribution layer 201 is made of copper, and the insulating layer 200 is made of a dielectric material such as polybenzoxazole (PBO), polyimide (PI), prepreg (PP) and the like, or a solder-proof material such as green paint, ink.

As shown in FIG. 2E, at least one second electronic component 26 is disposed on the circuit structure 20 and encapsulated with an encapsulation layer 28.

In an embodiment, it is shown that two second electronic components 26 are disposed on the circuit structure 20, wherein the second electronic component 26 is an active component, a passive component, or a combination thereof, and the active component is such as a semiconductor chip, while the passive component is a resister, a capacitor, and an inductor, for example. In an aspect of the embodiment, the second electronic component 26 is, for example, a semiconductor chip such as a graphics processing unit (GPU), a high bandwidth memory (HBM), etc., and is not particularly limited thereto.

Furthermore, the second electronic component 26 is electrically connected to the electrical contact pads 202 through a plurality of conductive bumps 27 such as solder bumps, copper bumps or others, and the encapsulation layer 28 can encapsulate the second electronic component 26 and the conductive bumps 27 at the same time.

In addition, the encapsulation layer 28 is an insulation material, such as polyimide (abbreviated as PI), a dry film, or an encapsulant or molding compound such as epoxy, which can be formed on the circuit structure 20 by such methods as lamination or compression molding. It should be understood that the encapsulation layer 28 may be made of the same or different from the material as the cladding layer 25.

In addition, an underfill 260 may be formed between the second electronic component 26 and the circuit structure 20 to encapsulate the conductive bumps 27 first, and then the encapsulation layer 28 may be formed to encapsulate the underfill 260 and the second electronic component 26.

Furthermore, a leveling process, such as grinding, can be used to remove a part of the material of the encapsulation layer 28, such that an upper surface of the encapsulation layer 28 is flushed with a surface of the second electronic component 26, so that the second electronic component 26 is exposed from the encapsulation layer 28.

As shown in FIG. 2F-1, the carrier 9 and the release layer 90 and the metal layer 9b on the carrier 9 are removed, and a circuit portion 24 is formed on the insulating layer 91 to electrically connect to the plurality of conductive pillars 23.

In an embodiment, while releasing the release layer 90, the metal layer 9b acts as a barrier to protect the insulating layer 91 from being damaged, and the metal layer 9b is removed by etching after the carrier 9 and the release layer 90 thereon are removed. By providing the carrier 9 with the insulating layer 91, the insulating layer 91 can be used to form the circuit portion 24 after the carrier 9 is removed, thereby eliminating the need to set a dielectric layer, saving process time and process steps to reduce process costs.

In an embodiment, a plurality of openings are formed in the insulating layer 91 by laser, such that the end surfaces 23b of the conductive pillars 23 and the second surface 25b of the cladding layer 25 are exposed from the openings, for bonding the circuit portion 24. For example, the circuit portion 24 includes an under bump metal (UBM) for bonding a plurality of conductive components 29 such as a plurality of solder bumps or solder balls (C4 type); or, the circuit portion 24 may be formed on the insulating layer 91 by an RDL process to be bonded to the conductive component 29.

Please refer to FIGS. 2F-1 and 2F-2 together. Subsequent to a singulation process, and a plurality of electronic packages 2 can be obtained, wherein the plurality of conductive pillars 23 of some of the electronic packages 2 are designed to be gradually thinner from the outside to the inside (as shown in FIG. 2F-1), and the plurality of conductive pillars 23 of some of the electronic packages 2 are designed to be gradually thicker from the outside to the inside (as shown in FIG. 2F-2), depending on the production process of each packaging unit recorded in advance or the final deformation direction is a crying face or a smiling face.

Therefore, in fabricating method of the present disclosure, it mainly records in advance that the (transverse) sizes of the conductive pillars are reduced from the outside to the center as the deformation direction of the packaging structure is a crying face, and the (transverse) sizes of the conductive pillars are increased from the outside to the center as the deformation direction of the packaging structure is a smiling face, so as to reduce the deformation problem by adjusting the diameter ratio of the conductive pillars, thereby improving yield. In addition, the aforementioned structure does not require the addition of new development processes and materials or the purchase of machines, the existing materials and the original processes and machines can be used to solve the industry's existing technical problems, so there will be no large additional costs.

The present disclosure also provides an electronic package 2, comprising: a cladding layer 25, a first electronic component 21 and a plurality of conductive pillars 23.

The cladding layer 25 has a first surface 25a and a second surface 25b opposing the first surface 25a.

The first electronic component 21 is embedded in the cladding layer 25, and a plurality of conductors 22 are bonded on and electrically connected to the first electronic component 21, wherein the plurality of conductors 22 are embedded in the cladding layer 25, and end surfaces 22a of the plurality of conductors 22 are exposed from the first surface 25a of the cladding layer 25.

The plurality of conductive pillars 23 are embedded in the cladding layer 25 and surround the first electronic component 21, wherein the diametric sizes of the plurality of conductive pillars 23 gradually increase or decrease from the outside to the center, and end surfaces 23a of the conductive pillars 23 are exposed from the first surface 25a of the cladding layer 25.

In an embodiment, the electronic package 2 further comprises a circuit structure 20, which is disposed on the first surface 25a of the cladding layer 25 and electrically connected to the plurality of conductive pillars 23 and the plurality of conductors 22.

In an embodiment, the electronic package 2 further comprises a second electronic component 26 that is disposed on the circuit structure 20 and electrically connected to the circuit structure 20.

In an embodiment, the electronic package 2 further comprises a circuit portion 24, which is formed on the second surface 25b of the cladding layer 25 and electrically connected to the plurality of conductive pillars 23.

In an embodiment, the first electronic component 21 has an active surface 21a and an inactive surface 21b opposing the active surface 21a, and the active surface 21 is bonded to and electrically connected to the plurality of conductors 22.

In an embodiment, the first surface 25a of the cladding layer 25 is flushed with the end surfaces 23a of the plurality of conductive pillars 23.

In an embodiment, the second surface 25b of the cladding layer 25 is flushed with other end surfaces 23b of the plurality of conductive pillars 23.

In an embodiment, the first surface 25a of the cladding layer 25 is flushed with end surfaces 22a of the plurality of conductors 22.

In an embodiment, the second electronic component 26 is disposed on the circuit structure 20 through a plurality of conductive bumps 27 to electrically connect to the circuit structure 20.

In an embodiment, the electronic package 2 further comprises an encapsulation layer 28 formed on the circuit structure 20, which encapsulates the second electronic component 26.

In summary, an electronic package and a method for fabricating the same according to embodiments of the present disclosure provide a package structure that can modulate the deformation direction, which changes the direction of deformation by dynamically adjusting the diametric sizes and arrangement of conductive pillars mainly, thereby overcoming the warpage problem.

The above embodiments are set forth to illustrate the principles of the present disclosure, and should not be interpreted as to limit the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. A method for fabricating an electronic package, the method comprising:
forming a plurality of conductive pillars on a carrier, and disposing a first electronic component on the carrier, wherein the plurality of conductive pillars surround the first electronic component, and diametric sizes of the plurality of conductive pillars gradually increase or decrease from an outside to a center of the carrier;
forming a cladding layer on the carrier to encapsulate the first electronic component and the plurality of conductive pillars, wherein the cladding layer has a first surface and a second surface opposing the first surface, the cladding layer is bonded to the carrier with the second surface thereof, and end surfaces of the plurality of conductive pillars are exposed from the first surface of the cladding layer; and
removing the carrier.

2. The method of claim 1, further comprising forming a circuit structure on the first surface of the cladding layer to electrically connect the plurality of conductive pillars and the first electronic component.

3. The method of claim 2, further comprising disposing a second electronic component on the circuit structure which is not in contact with the cladding layer, and electrically connecting the second electronic component to the circuit structure.

4. The method of claim 3, further comprising forming an encapsulation layer on the circuit structure which is not in contact with the cladding layer to encapsulate the second electronic component.

5. The method of claim 3, wherein the second electronic component is disposed on the circuit structure through a plurality of conductive bumps and electrically connected to the circuit structure.

6. The method of claim 1, wherein the first electronic component is bonded with and electrically connected to a plurality of conductors.

7. The method of claim 1, further comprising forming a circuit portion on the second surface of the cladding layer to electrically connect the plurality of conductive pillars.

8. The method of claim 7, further comprising forming a plurality of conductive components on the circuit portion.

9. The method of claim 1, which is performed on a wafer comprising a plurality of packaging units, and an entire semi-finished product of the wafer is produced station by station in advance, wherein the diametric sizes of the plurality of conductive pillars are kept uniform, then warping contours of each of the packaging units in process are recorded, and warping contours of each of the packaging units after singulation are recorded, so as to design a distribution of the diametric sizes of the plurality of conductive pillars in accordance with the recorded warping contours, such that the diametric sizes of the plurality of conductive pillars are designed to decrease from the outside to the center of the carrier when a deformation direction of the packaging units is a crying face, and the diametric sizes of the plurality of conductive pillars are designed to increase from the outside to the center of the carrier when the deformation direction of the packaging units is a smiling face.

10. An electronic package, comprising:
a cladding layer having a first surface and second surface opposing the first surface;
a first electronic component is embedded in the cladding layer; and
a plurality of conductive pillars embedded in the cladding layer and surrounding the first electronic component, wherein diametric sizes of the plurality of conductive pillars increase or decrease gradually from an outside to a center with respect to the cladding layer, and end surfaces of the plurality of conductive pillars are exposed from the first surface of the cladding layer.

11. The electronic package of claim 10, further comprises a circuit structure, which is formed on the first surface of the cladding layer and electrically connected to the plurality of conductive pillars and the first electronic component.

12. The electronic package of claim 11, further comprises a second electronic component disposed on the circuit structure which is not in contact with the cladding layer and electrically connected to the circuit structure.

13. The electronic package of claim 12, wherein the second electronic component is disposed on and electrically connected to the circuit structure through a conductive bump.

14. The electronic package of claim 12, further comprises an encapsulation layer formed on the circuit structure which is not in contact with the cladding layer to encapsulate the second electronic component.

15. The electronic package of claim 10, wherein the first electronic component is bonded with and electrically connected to a plurality of conductors.

16. The electronic package of claim 10, further comprises a circuit portion, which is formed on the second surface of the cladding layer and electrically connected to the plurality of conductive pillars.

17. The electronic package of claim 16, further comprises a plurality of conductive components formed on the circuit portion.

18. The electronic package of claim 10, which is performed on a wafer comprising a plurality of packaging units, and an entire semi-finished product of the wafer is produced station by station in advance, wherein the diametric sizes of a plurality of conductive pillars are uniform, then warping contours of each of the packaging units presented in process are recorded, and warping contours of each of the packaging units after singulation are recorded, so as to design a distribution of the diametric sizes of the plurality of conductive pillars in accordance with the recorded of the warping contours, such that the diametric sizes of the plurality of conductive pillars are designed to decrease from the outside to the center with respect to the cladding layer when a deformation direction of the packaging units is a crying face, and the diametric sizes of the plurality of conductive pillars are designed to increase from the outside to the center with respect to the cladding layer when the deformation direction of the packaging units is a smiling face.
